(19) United States
(12) Patent Application Publication
(10) Pub. No.: US 2025/0202468 A1
(43) Pub. Date: Jun. 19, 2025

(54) Systems and Devices of a Pulse Generator

(71) Applicant: Arm Limited, Cambridge (GB)

(72) Inventors: El Mehdi Boujamaa, Valbonne (FR); Franck Gregory Ciotti, Nice (FR)

(21) Appl. No.: 18/985,258

(22) Filed: Dec. 18, 2024

(30) Foreign Application Priority Data
Dec. 18, 2023 (GB) 2319373.3

(51) Int. Cl. H03K 5/135; H03K 3/017; H03K 5/00; H03K 5/14

(52) U.S. Cl. CPC H03K 5/135; H03K 3/017; H03K 5/14; H03K 2005/00019; H03K 2005/00234

(57) ABSTRACT

According to one implementation, a pulse generator circuit includes a flip-flop receiving an input clock signal, and one or more delay elements where the circuit is configured to adjust a pulse width of an output clock signal independent of a clock period of the input clock signal. According to another implementation, a pulse generator circuit includes a flip-flop receiving an input clock signal, and one or more delay elements where the circuit is configured to adjust a pulse width of an output clock signal. The flip-flop is configured to transmit a flip-flop output signal to the one or more delay elements where the flip-flop output signal includes a state of the flip-flop. The one or more delay elements are configured to delay the flip-flop output signal by a delay period and transmit the delayed flip-flop output to a reset input.

### FIELD

The present disclosure is generally related to the systems and devices of a pulse generator circuit.

### DESCRIPTION OF THE RELATED ART

This section is intended to provide information relevant to understanding various technologies described herein. As the section's heading implies, this is a discussion of related art that in no way implies that the discussion is prior art. Generally, related art may or may not be considered prior art. Any statement in this section should be read in this light, and not as admission of prior art.

Droop detectors and delay monitors are gate delay-based voltage droop sensors. While a droop detector focuses on voltage stability, a delay monitor focuses on timing and synchronization within a system. Accordingly, droop detectors and delay monitors are often used in applications like high-speed communication, signal processing, high-speed processors, and precision control systems. Further, both droop detectors and delay monitors play roles in maintaining the reliable and accurate operation of digital systems.

### BRIEF DESCRIPTION OF THE DRAWINGS

Implementations of various techniques are described herein with reference to the accompanying drawings. The accompanying drawings illustrate various implementations described herein and are not meant to limit embodiments of various techniques described herein.

FIG. 1A is a diagram, in accordance with certain implementations.

FIG. 1B is a diagram, in accordance with certain implementations.

FIG. 1C is a diagram, in accordance with certain implementations.

FIG. 1D is a diagram, in accordance with certain implementations.

FIG. 1E is a diagram of FIG. 1C.

FIG. 2A is a diagram, in accordance with certain implementations.

FIG. 2B is a diagram of FIG. 2A.

FIG. 3 is a diagram, in accordance with certain implementations.

FIG. 4A is a diagram, in accordance with certain implementations.

FIG. 4B is a diagram, in accordance with certain implementations.

Reference is made in the following detailed description to accompanying drawings, that form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, and the like), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

According to one implementation of the present disclosure, a flop-based clock pulse generator circuit includes a flip-flop receiving an input clock signal (ckin) and one or more delay elements where the circuit is configured to adjust a pulse width of an output clock signal (ck) independent of a clock period of the input clock signal (ckin).

According to another implementation of the present disclosure, a flop-based clock pulse generator circuit includes a flip-flop receiving an input clock signal (ckin), and one or more delay elements where the circuit is configured to adjust a pulse width of an output clock signal (ck). The flip-flop is configured to transmit a flip-flop output signal (ckff) to the one or more delay elements where the flip-flop output signal includes a state of the flip-flop. The one or more delay elements are configured to delay the flip-flop output signal (ckff) by a delay period (ts) and transmit the delayed flip-flop output (ckffd) to a reset input.

Schemes and techniques, as described herein, relate to an inventive pulse generator circuit configured as a clock edge filter to provide an output clock pulse (i.e., output clock signal) that may be trimmable beyond a half period of an input clock signal and up to a full period (i.e., clock cycle) of the input clock signal. In certain implementations, a calibration interval (i.e., t₁, the interval between an end of the output clock pulse and the next input clock signal rising edge) may also be trimmable, based on the trimmable output clock pulse. Advantageously, clarity in resolution may be achieved based on a size of the calibration interval, since such an interval can determine a number of gates in a gate delay-based voltage droop sensor used for a thermometer coded output. Other schemes and techniques relate to the inventive pulse generator circuit configured to provide a time delay adjustment (ts) to a trimmable output clock pulse, where the trimmable output clock pulse width can be greater than or equal to 2tₛ. Furthermore, as another advantage, a delay line of the inventive pulse generator circuit may be reduced in size by half.

Certain definitions have been provided herein for reference. As may be appreciated, synchronous pulse generation is a process that generates pulses or signals with precise timing and synchronization to a reference clock or another signal. Synchronous pulse generation is commonly used in digital systems, communication, and signal processing applications where accurate timing is desired. For instance, in synchronous pulse generation, the timing of the pulses may be precisely synchronized with a reference signal, such as an input clock signal (ckin). In doing so, the occurrence of pulses at specific intervals and phases to ease control and coordination of various components within a digital system may be ensured. Correspondingly, many synchronous pulse generation systems rely on a master clock signal that provides a reference for generating other pulses. Also, such pulses may be generated at specific clock edges or intervals, ensuring consistent and predictable timing. Such synchronous pulse generation is commonly used in applications such as data transmission, digital communication, memory interfaces, and microprocessor systems. In addition, synchronous pulse generation can help ensure that data is transmitted or processed with accurate timing, reducing the risk of data corruption or errors. One advantage of synchronous pulse generation is precision and accuracy. By minimizing timing jitter and drift, synchronous pulse generation would be suitable for applications where signal integrity and synchronization are desired. In addition, pulse generators allow for precise control over pulse width (duration) and frequency. Such control over pulse width (duration) and frequency control is valuable for applications that require specific timing characteristics. In test and measurement applications also, synchronous pulse generation can be used for triggering and accurate sampling signals, as such pulse generation provides for consistent and repeatable measurements.

As one might understand, a droop detector is a circuit or component used to monitor and detect voltage droop or transient voltage changes in a power supply. Voltage droop occurs when there is a temporary reduction in the supply voltage, typically due to a sudden increase in the load. Accordingly, the purpose of a droop detector is to sense these voltage variations and trigger a response, such as providing additional power or activating protective mechanisms to stabilize the voltage. Therefore, droop detectors are commonly used in power management systems to ensure that electronic devices or circuits receive consistent and stable power, even during transient load changes.

Also, a delay monitor is a circuit or component used to measure and monitor the time delay introduced by various elements within a system. Correspondingly, the purpose of a delay monitor is to ensure that signals or processes occur with an expected timing. Thus, a delay monitor is often used in applications where precise timing and synchronization are desired, such as in a high-speed computational circuits. Further, a delay monitor is used to verify that signals arrive at specific points in a system with the correct timing relationships. Additionally, in cases where delay adjustments are desired, a delay monitor would provide feedback for compensation or correction.

In addition, a thermometer-coded delay line refers to a delay line that uses a thermometer code to represent the delay introduced at each stage of the delay line, such as a delay monitor. The output of a thermometer code delay line is a binary encoding where each stage corresponds to a specific time delay increment, and one bit is “high” (1) at a time. As an example, the position of the “high” bit indicates the delay value for that stage.

In a non-limiting example of a 4-bit thermometer-coded delay line:
‘0001’: Indicates the shortest delay.
‘0011’: Slightly longer delay.
‘0111’: Longer delay.
‘1111’: Longest delay.

It can be recognized that the output of a thermometer-coded delay line is a signal that has been delayed in discrete steps based on the thermometer code. Namely, the specific combination of high and low bits in the output signal represents the cumulative delay introduced at each stage of the delay line. Thus, the output signal can be used in various applications, such as signal alignment, time-domain adjustments, and synchronization in digital systems.

Moreover, a delay line is a device or circuit used to introduce a controlled and specific delay into an electrical or electronic signal. The purpose of a delay line is to shift the timing of a signal by a predetermined amount, such as a delay period (ts), while preserving the signal's characteristics. Thus, a delay line is commonly used in various applications in electronics, telecommunications, and signal processing.

In current pulse generator designs, the inability to “trim” (e.g., shorten or lengthen) up to a full input clock signal (ckin) period remains a significant issue preventing the capacity to flexibly adjust the calibration interval (t₁), and hence, preventing precise control of a clock signal. In such designs, an output clock signal (ck) pulse width is commonly greater than or equal to a delay period (tₛ) due to delays of other logic gates. While the delay period (tₛ) may be able to be trimmed (e.g., either shortened or lengthened), the delay period (tₛ) is unable to be greater than half of the input clock signal (ckin) period due to the falling edge of the input clock signal (ckin) causing the output clock signal (ck) pulse to terminate. That is, in known designs, at the falling edge (indicating half the input clock signal (ckin) with a 50% duty cycle (e.g., the ratio between a high state duration and the period) of the clock) of the input clock signal (ckin), one input is at a digital high state (1) and the other input is at a digital low state (0); and so, such designs would output a digital high state that terminates the clock signal (ck) pulse. It can be understood, for such designs, as the delay period (tₛ) increases to greater than half the input clock signal (ckin) period (

$${t}_{s} > \frac{1}{2} ckin cycle e . g . ,$$

a 50% duty cycle), the output clock signal (ck) pulse width (i.e., the output clock signal (ck) in a digital low state (0)) begins to contract. Hence, a greater delay period (tₛ) does not result in a greater output clock signal (ck) pulse width and, in fact, the clock signal (ck) pulse width stops increasing once

$${t}_{s} > \frac{1}{2} ckin cycle .$$

Further, in response to the duty cycle being below 50%, for example 30%, then the clock signal (ck) pulse width stops increasing once

$${t}_{s} > \frac{3}{10} ckin cycle .$$

Therefore, for presently known designs, trimming of the output clock signal (ck) pulse width is limited by the input clock signal (ckin) and more specifically the falling edge of the input clock signal (ckin).

In digital systems, as defined herein, a clock period is the time duration between two consecutive rising (or falling) edges of the clock signal. The clock period determines the timing and synchronization of various operations within a digital system. As this clock period determines the timing and synchronization, “trimming” a pulse to a “full” clock period (according to the inventive aspects) can be performed such that a specific operation or action occurs within a precise calibration interval (t₁) defined by the clock signal and the delay line length.

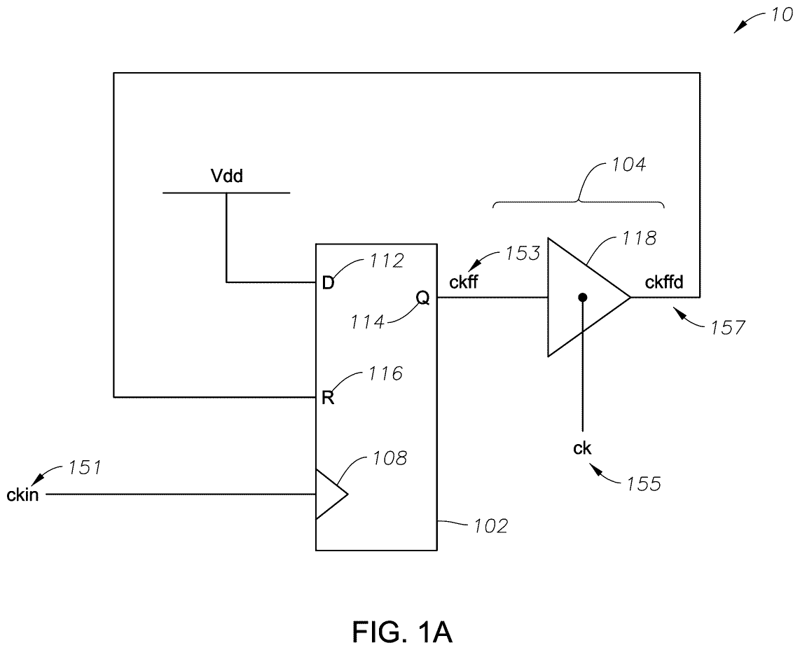

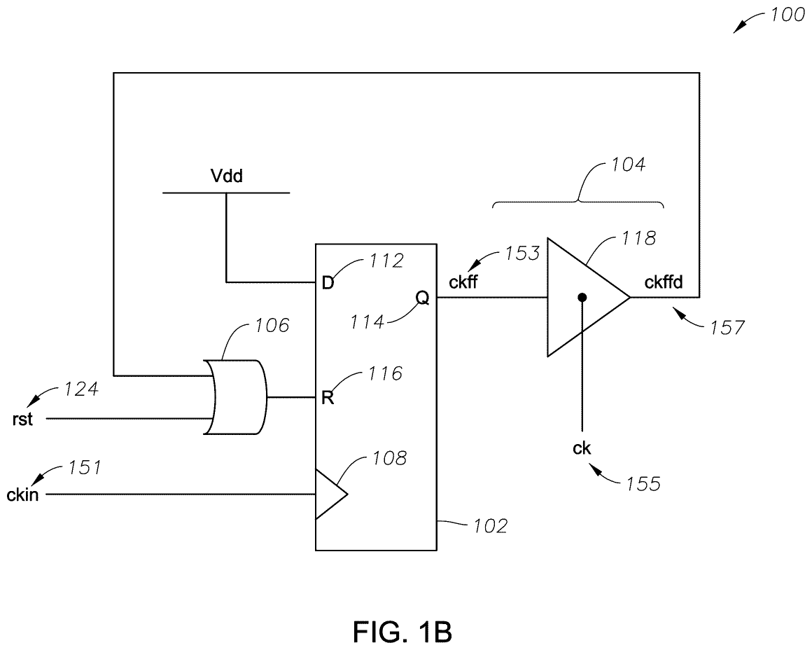

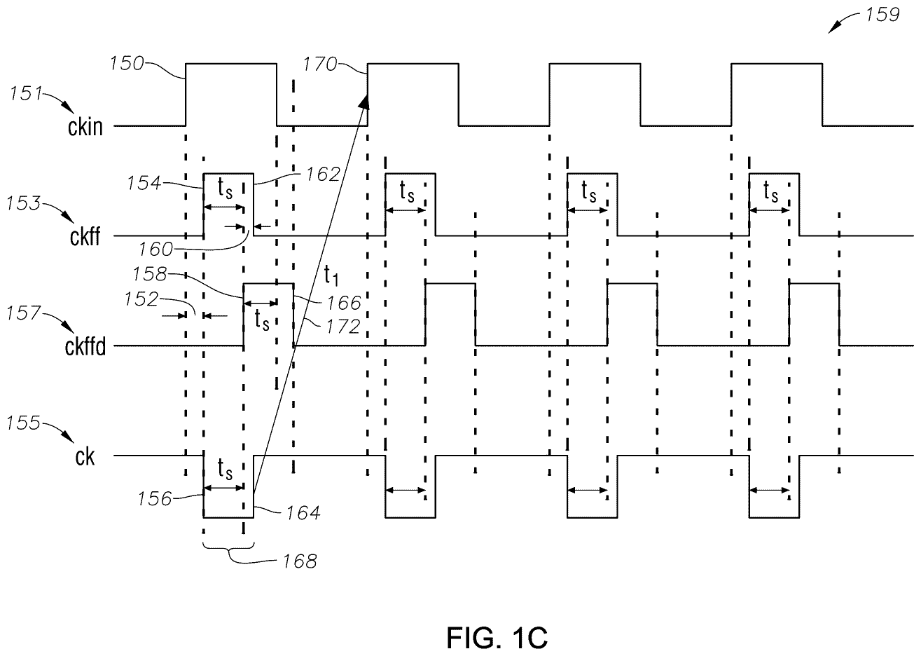

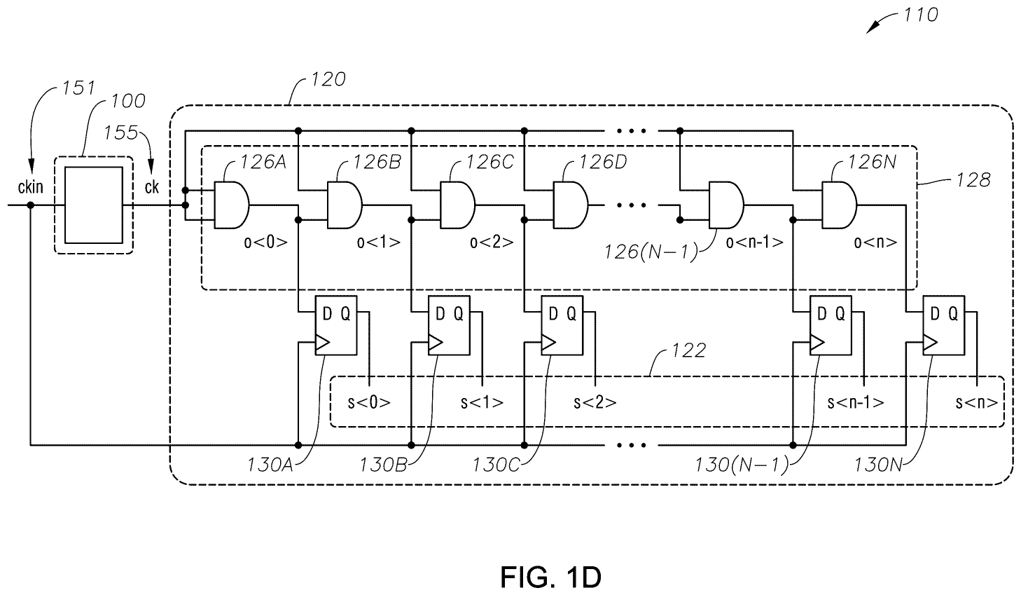

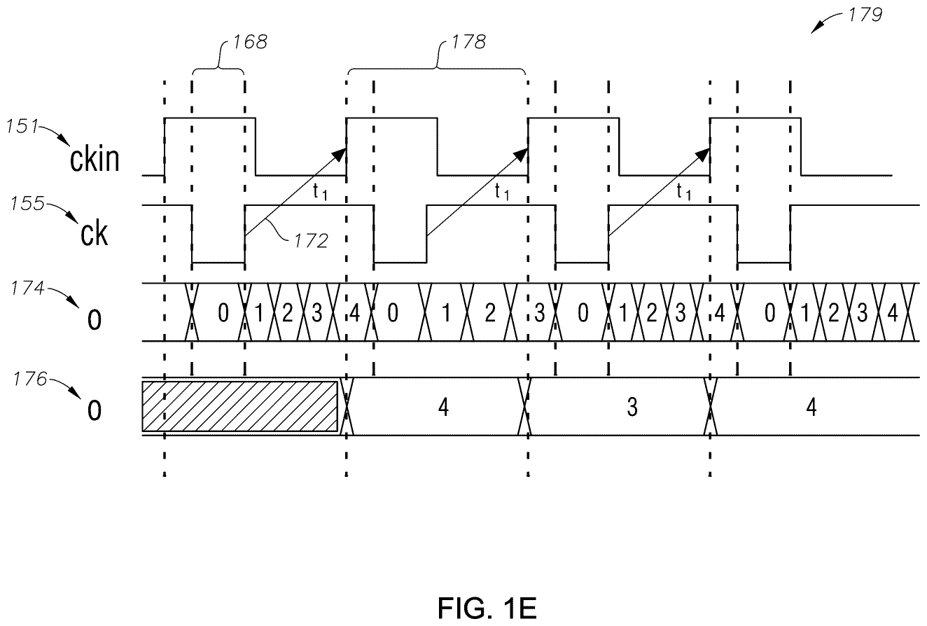

FIG. 1A is a block diagram of an example pulse generator circuit 10, in accordance with certain implementations. FIG. 1B is a block diagram of an example pulse generator circuit 100, in accordance with certain implementations. FIG. 1C is a timing diagram representation 159 of the example pulse generator circuit 10 as illustrated in FIG. 1A or the example pulse generator circuit 100 as illustrated in FIG. 1B.

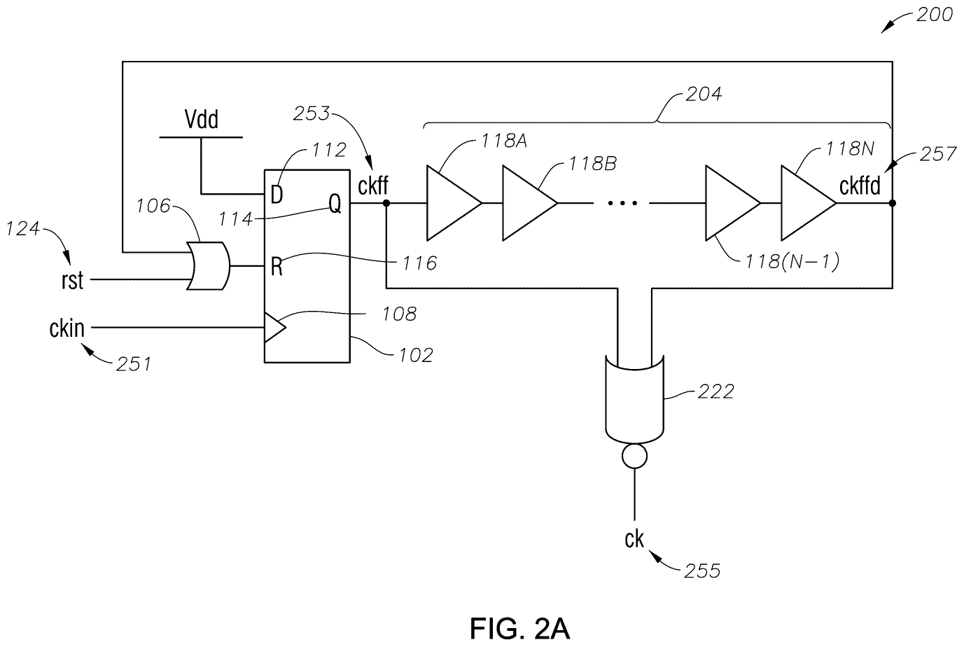

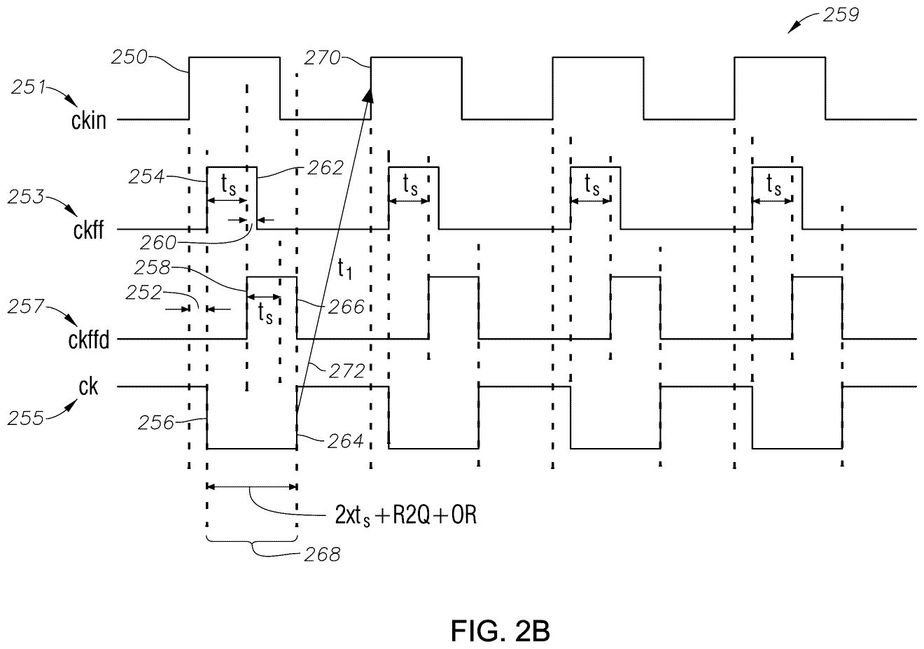

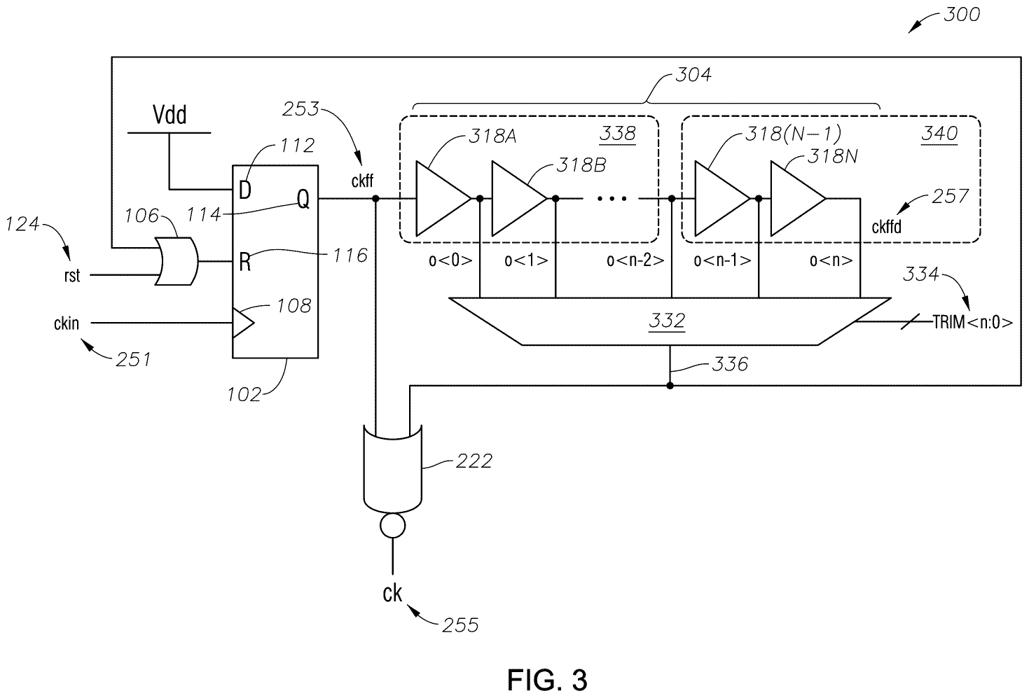

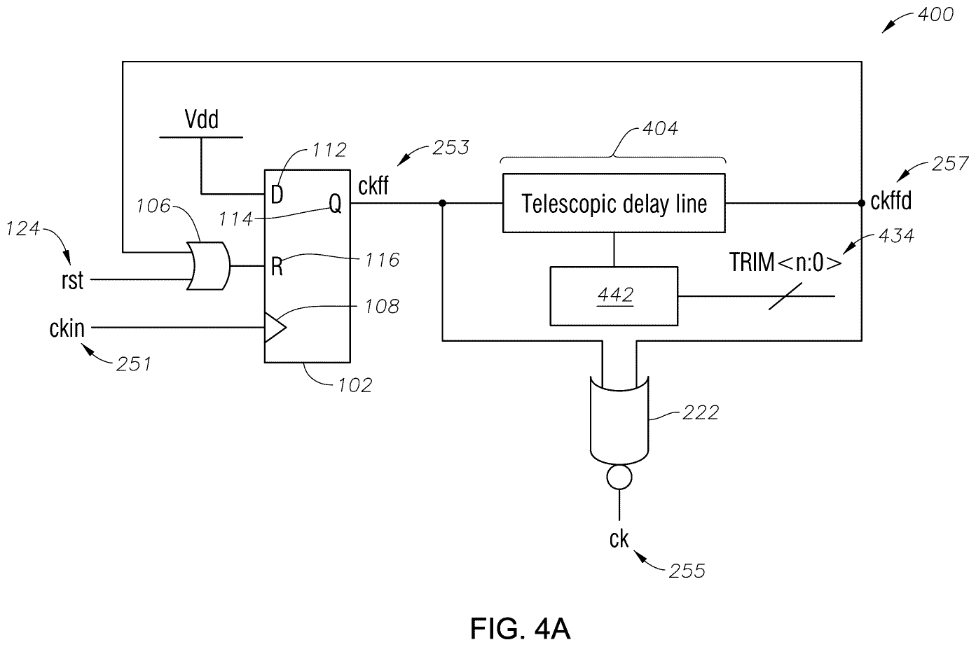

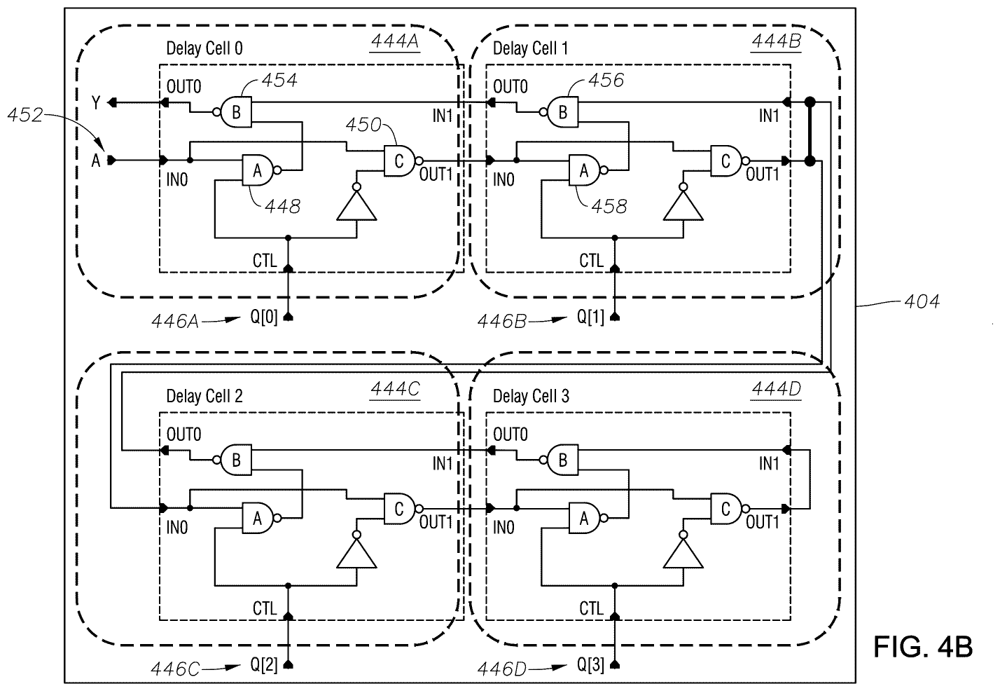

In various implementations, each of the example pulse generator circuits 10, 100 (FIG. 1B), 200 (FIG. 2A), 300 (FIG. 3), and 400 (FIG. 4A) as illustrated in FIGS. 1A, 1B, 2A, 3, and 4A can be implemented as a system or a device having various integrated circuit (IC) components that are arranged and coupled together as an assemblage or combination of parts that provide for a physical circuit design and related structures. Further, each of the example pulse generator circuits 10, 100 (FIG. 1B), 200 (FIG. 2A), 300 (FIG. 3), and 400 (FIG. 4A) can be integrated with computing circuitry and related components on multiple chips, and are further able to be implemented in embedded systems for automotive, electronic, mobile and Internet-of-things (IoT) applications.

As illustrated in FIG. 1A, the example pulse generator circuit 10 includes a flip-flop 102, and a delay line 104. As may be appreciated, the flip-flop 102 can be a bistable multivibrator, as the flip-flop 102 can have two stable states and stores one bit of digital information (e.g., 0 (digital low state) or 1 (digital high state)). The two stable states are a set state (typically representing logic 1) and a reset state (typically representing logic 0). The flip-flop 102 stores one bit of information, and remains in one of these states until receiving a triggering signal. Sometimes called a clock or trigger input, input clock signal (ckin) 151 changes the state of the flip-flop 102. In an inventive aspect, the flip-flop 102, as a clock edge filter, can respond to the rising edge of the input clock signal (ckin) 151 and be unaffected by the falling edge of the input clock signal (ckin) 151. It is understood, a clock edge filter, in the context of digital electronics, is a circuit or component designed to condition and filter clock signals, particularly focusing on the detection of specific clock edges (rising edges or falling edges) while rejecting noise or unwanted transitions. Further, a clock edge filter plays a role in ensuring the reliability and stability of clock signals in digital systems.

In certain implementations, data input (D) 112 allows the setting or resetting of the flip-flop's state when the input clock signal (ckin) 151 triggers the flip-flop 102. As such, the data input (D) 112 determines whether the flip-flop 102 is switched to the set state (logic 1) or the reset state (logic 0).

As illustrated in FIG. 1A, the data input (D) 112 is tied to a digital high state (1) with Vdd (e.g., a power supply voltage) meaning the data input 112 is a logic 1. Conversely, flip-flop output (Q) 114 outputs the stored state of the flip-flop 102. Representatively, flip-flop output (ckff) 153 is the current state of the flip-flop 102 and changes in response to the input clock signal (ckin) 151 and the data input (D) 112. Continuing, in response to a logic signal being applied to a reset input (R) 116 (i.e., a reset signal), the reset input 116 (sometimes labeled as CLR, RST, RESET, or the like) initiates a reset operation. In response to the reset signal, the flip-flop 102 responds by setting to the reset state. However, the specific behavior of this operation depends on the type of flip-flop and design. In most cases, a reset operation forces the flip-flop output (ckff) 153 to a predetermined logic level (typically logic 0).

As illustrated in FIG. 1A, the delay line 104 includes delay element 118. The delay line 104 can be used to introduce a controlled delay period (tₛ) into the flip-flop output (ckff) 153 that results in a delayed output (ckffd) 157. Also, the delay line 104 shifts the timing of the flip-flop output (ckff) 153 by a predetermined amount (i.e., the delay period (tₛ)) while preserving the characteristics of the flip-flop output (ckff) 153. As shown, the delay element 118 is represented as a buffer, that is, an electronic component or circuit that serves to strengthen or amplify signals. A representative buffer receives an input signal, such as the flip-flop output (ckff) 153, and produces an output signal, such as the delayed output (ckffd) 157, that, in certain aspects, can be an exact replica of the input but with enhanced strength. One of ordinary skill in the art appreciates that the buffer can be a complementary metal-oxide-semiconductor (CMOS) buffer, a non-inverting buffer, or an inverting buffer. Further, a buffer may be an RC delay, ring oscillator, a delay-locked loop, or a shift register without departing from the spirit of the implementations.

For purposes of this discussion, the delay element 118 includes a pair of inverters in series. As may be appreciated, one or more digital inverters (not shown), that make up the delay element 118, are digital logic gates that perform the logical operation of inversion or NOT operation. In other words, an inverter takes an input, such as the flip-flop output (ckff) 153, and produces an output, such as (c̅k̅f̅f̅), that is the logical complement of the input. For example, in response to the input being high (1), the output is low (0), and vice versa. Summarily, the primary function of an inverter is to reverse the logical state of a signal, such as the flip-flop output (ckff) 153, that may be output clock signal (ck) 155.

Advantageously, as described herein, in certain cases, the pulse generator circuit 10 can be configured to adjust (e.g., control) output signal (ck) pulse width 168 of the output clock signal (ck) 155 independent of a clock period of the input clock signal (ckin) 151. Correspondingly, the output clock signal (ck) pulse width 168 is a duration of the output clock signal (ck) 155 (set) at a digital low state (e.g., a digital “0”). To enable adjustment of the output clock signal (ck) pulse width 168, inventive aspects provide the capacity to increase or decrease the duration of the output clock signal (ck) 155 set at the digital low state within the clock period of the input clock signal (ckin) 151. It can be understood the clock period of the input clock signal (ckin) 151 corresponds to a duration from a first rising edge 150 to a second rising edge 170 of the input clock signal (ckin) 151 (at an input of the flip-flop 102).

In various implementations, a duration between the output clock signal (ck) pulse width 168 and the next rising edge of input clock signal (ckin) may be defined as a calibration interval 172 (e.g., “timing window”) (e.g., t1). In particular, a calibration interval, measurement window, or timing window refers to a specific period during which measurements, evaluations, or calibration processes occur in various systems, for example, electronics, instrumentation, and communication protocols. Representatively, the calibration interval 172 is a designated time span or duration during which certain operations or evaluations take place. To illustrate, a calibration interval 172 could denote the time frame allocated for adjusting or fine-tuning parameters to ensure accuracy or proper functioning. Additionally, the calibration interval 172 can serve a purpose, such as conducting measurements, performing calibrations, or assessing the timing of events or signals. Further, the calibration interval's duration is often carefully defined and aligned with the requirements of the system or process to ensure accurate measurements, calibration, or synchronization.

In addition, the pulse generator circuit 10 is configured to adjust the output signal (ck) pulse width 168 of the output clock signal (ck) 155 by modifying a duration of the flip-flop output (ckff) 153 at a digital high state (i.e., a digital “1”), where the flip-flop output (ckff) 153 corresponds to the input of the delay element 118. Further, the delay element 118 is configured to delay the flip-flop output (ckff) 153 by the delay period (e.g., tₛ), and transmit the delayed flip-flop output (ckffd) 157 to reset input 116.

As illustrated in FIGS. 1A and 1C, according to an example operation, in response to the first rising edge 150 of the input clock signal (ckin) 151 at clock input 108, a delay 152 occurs as the state of the flip-flop 102 is outputted (colloquially stated as clock to Q or ck2Q the time taken by the flip-flop 102 to propagate Vdd to the Q 114 after the input clock signal (ckin) transitions). After the delay 152, the state of the flip-flop 102 (i.e., a digital high state (1)) is realized in a rising edge 154 of the flip-flop output (ckff) 153. Further, the state of the flip-flop 102 is inverted (i.e., by a first inverter in the delay element 118) and a falling edge 156 of the output clock signal (ck) 155 is realized as the output clock signal (ck) 155 becomes a digital low state (0). After the delay period (tₛ), that is the time to pass the flip-flop output (ckff) 153 through the delay line 104, a rising edge 158 (i.e., the digital high state (1) reaching the end of the delay line 104) of the delayed output (ckffd) 157 is realized. Additionally, the rising edge 158 of the delayed output (ckffd) 157 transmits a digital high state (1) to the reset input 116 resetting the flip-flop 102 to a digital low state (0). Another delay, a R2Q (i.e., where R2Q is the delay from the reset input 116 to the Q output 114 of the flip-flop 102) delay 160 caused by the flip-flop 102 occurs before falling edge 162 of the flip-flop output (ckff) 153 (i.e., indicating the reset of the flip-flop to a digital low state (0)) and rising edge 164 of the output clock signal (ck) 155 (i.e., indicating the inversion of the flip-flop digital low state (0)). Mathematically, the output clock signal (ck) pulse width 168 may be represented as: tₛ+R2Q, or alternatively stated as the time through the delay line 104 and the flip-flop 102.

Next, as the flip-flop output (ckff) 153 passes through the delay line 104, the falling edge 162 of the flip-flop output (ckff) 153 can be realized as a falling edge 166 of the delayed output (ckffd) 157. As can be appreciated, the time between the rising edge 164 and the next rising edge 170 of the input clock signal (ckin) 151 is the calibration interval (t₁) 172. Consequently, for instance, the longer the output clock signal (ck) pulse width 168, the shorter the calibration interval (t₁) 172 would be, and the shorter the output clock signal (ck) pulse width 168, the longer the calibration interval (t₁) 172. Additionally, as the delay period (tₛ) is trimmed (e.g., meaning the output clock signal (ck) pulse width 168 is trimmed), the calibration interval (t₁) 172 may be trimmed as well. As described, according to the various inventive aspects, the delay period (tₛ) can be trimmed up to a full period of the input clock signal (ckin) 151; and thus, resulting in the calibration interval (t₁) 172 going to zero or near zero.

As illustrated in FIGS. 1A and 1C, in an example operation, a digital high state (1) may be initially set at the reset input 116. By doing so, the flip-flop 102 can be forced to reset while the flip-flop output (ckff) 153 and the delayed output (ckffd) 157 may be forced to a digital low state (0). Also, the input clock signal (ckin) 151 may be initially set at a digital low state (0). Next, in response to the input clock signal (ckin) 151 transitioning between a digital low state (0) to a digital high state (1) (i.e., the first rising edge 150) and after the delay 152 of the flip-flop 102, the flip-flop output (ckff) 153 transitions from a digital low state (0) to a digital high state (1). Further, the digital high state (1) of the flip-flop output (ckff) 153 remains until the digital high state (1) arrives at the delayed output (ckffd) 157 and is transmitted to the reset input 116. As the delayed output (ckffd) 157 is operably connected to the reset input 116, the flip-flop output (ckff) 153 transitions to a digital low state (0).

Continuing with such an example, after the delay period (tₛ), the transition at the delayed output (ckffd) 157 from digital low state (0) to digital high state (1) causes the transition at the flip-flop output (ckff) 153 to return to a digital low state (0). Thus, a transition from the digital high state (1) to the digital low state (0) of the flip-flop output (ckff) 153 takes approximately the delay period (tₛ) to be seen at the delayed output (ckffd) 157.

In certain implementations, as illustrated in FIG. 1B, gate 106 is an OR gate and is configured to perform a logical OR operation. Further, the gate 106 has two or more inputs (i.e., rst and the delayed output (ckffd) 157) and produces an output that is high (1) in response to at least one of the inputs being in a digital high state (1) and low (0) in response to each input being in a digital low state (0).

In various cases, the delay element 118 is configured to delay the flip-flop output (ckff) 153 by the delay period (tₛ), and transmit the delayed flip-flop output (ckffd) 157 to a first input of the gate 106. As illustrated in FIG. 1B, the gate 106 is configured to receive reset signal 124 at a second input of the gate 106.

As illustrated in FIGS. 1B and 1C, in an example operation, the reset signal 124 is initially set at a digital high state (1) at the reset input 116 and the flip-flop 102 is forced to reset to a digital low state (0). To obtain a known initial state on the flip-flop 102, the reset is performed. In response to the flip-flop 102 being reset, ideally the flip-flop output (ckff) 153 is left at a digital low state (0) “sufficiently long” until the delayed output (ckffd) 157 is at a digital low state (0) as well to ensure the reset passes through the delay element circuit 100. Thus, the working state of the reset is 0 or a digital low state.

Next, in response to the first rising edge 150, a delay 152 would occur as the state of the flip-flop 102 is outputted. After the delay 152, a rising edge 154 of the flip-flop output (ckff) 153 and a falling edge 156 of the output clock signal (ck) 155 are realized. After the delay period (tₛ), that is the time to pass the flip-flop output (ckff) 153 through the delay line 104, a rising edge 158 of the delayed output (ckffd) 157 is realized. The rising edge 158 of the delayed output (ckffd) 157 is transmitted to the gate 106, that respectively transmits a digital high state (1) to the reset input 116 causing the flip-flop 102 to be reset. In addition, a delay 160 caused by the gate 106 and the flip-flop 102 (e.g., R2Q) occurs before falling edge 162 of the flip-flop output (ckff) 153 and rising edge 164 of the output clock signal (ck) 155. Mathematically, the output clock signal (ck) pulse width 168 can be represented as tₛ+OR+R2Q, or alternatively stated as the time through the delay line 104, the gate 106, and the flip-flop 102.

FIG. 1D is a block diagram representation of an example voltage droop detector 110, in accordance with certain implementations. FIG. 1E is a timing diagram representation 179 of the voltage the voltage droop detector circuit 110 as illustrated in FIG. 1C.

As illustrated in FIGS. 1D and 1E, the voltage droop detector circuit 110 includes the pulse generator circuit 10 or 100 and voltage droop sensor 120. As stated above, to improve robustness or clarity in resolution of a thermometer coded delay line output 122, the pulse generator circuit 10 or 100 is configured to produce a trimmable output clock signal (ck) pulse width, such as the output clock signal (ck) pulse width 168. For purposes of the present discussion, higher resolution refers to a greater level of detail or clarity.

In an example operation, the output clock signal (ck) 155 is transmitted to AND gates 126A, 126B, 126C, 126D, . . . 126(N-1), and 126N. In response to the output clock signal (ck) 155 being a digital low state (0) for a pre-determined period, outputs o<0>, o<1>, o<2>, o<n-1>, and o<n> of the AND gates 126A, 126B, 126C, 126D, . . . 126(N-1), and 126N are set to a digital low state (0). Setting of the digital low state (0) for the AND gates 126A, 126B, 126C, 126D, . . . 126(N-1), and 126N takes one gate delay (i.e., the time taken for a logic gate to produce an output signal in response to a change in the input signal). Thus, the digital low state (0) can propagate through delay line 128 (e.g., a delay monitor) “very quickly” (e.g., in one gate delay or approximately 10 ps). Continuing with such an example, in response to the output clock signal (ck) 155 transitioning to a digital high state (1), the AND gates 126A, 126B, 126C, 126D, . . . 126(N-1), and 126N transition to the digital high state (1) value sequentially (e.g., one after the other). For example, after a delay of first AND gate 126A, output o<0> transitions to a digital high state (1), then after a delay of second AND gate 126B, output o<1> transitions to a digital high state (1) and so on down the delay line 128 if the calibration interval (t₁) 172 is “wide enough” (e.g., long enough in time) to transition each AND gate to the digital high state.

Continuing, flip-flops 130A, 130B, 130C, . . . 130 (N-1), and 130N capture a respective transition to a digital high state (1) and in response to a rising edge, such as the next rising edge 170, of the clock input signal (ckin) 151, the flip-flops 130A, 130B, 130C, . . . 130 (N-1), and 130N output their respective states as the thermometer coded delay line output 122.

In another example, in response to the output clock signal (ck) 155 (at a digital high state (1)), upon “transitioning through” the first four AND gates 126A, 126B, 126C, 126D when a rising edge of the input clock signal (ckin) 151 is received at the flip-flops 130A, 130B, 130C, . . . 130 (N-1), and 130N, the outputs (e.g., o<0>, o<1>, o<2>, o<n-1>, and on>) are captured by the flip-flops 130A, 130B, 130C, . . . 130 (N-1), and 130N and output to the thermometer coded delay line output 122. For instance, since the output clock signal (ck) 155 propagated only through the first four and gates before the rising edge of the input clock signal (ckin) 151, just the first four flip-flops output a digital high state (1) and the remaining flip-flops output a digital low state (0). As illustrated, output 174 represents the number of AND gates (4) the digital high state (1) at the output clock signal (ck) 155 was able to propagate through before the rising edge of clock input signal (ckin) 151 triggered the flip-flops 130A, 130B, 130C, . . . 130 (N-1), and 130N to output their respective states. Additionally, during the output clock signal (ck) pulse width 168, the output 174 is zero (as the output clock signal (ck) 155 is at a digital low state (0)).

Moreover, during the rising edge of the next input clock signal (ckin) period 178, the process of the pulse generator circuit 10 or 100 repeat. Once again, the rising edge of the input clock signal (ckin) 151 triggers the output clock signal (ck) pulse width 168, that correspondingly, triggers the AND gates 126A, 126B, 126C, 126D, . . . 126(N-1), and 126N to a digital low state (0). Next, the output clock signal (ck) pulse width 168 resets the delay line 128. In response to the transition to a digital high state (1) of the output clock signal (ck) 155, the digital high state (1) propagates through the delay line 128, and at the rising edge of the input clock signal (ckin) 151 the thermometer coded output 176 is captured.

As stated above, the calibration interval (t₁) 172 (i.e., the digital high state of the output clock signal 155) represents a timing window for a digital high state (1) of the output clock signal (ck) 155 to propagate into the delay line 128. Therefore, the “smaller” (e.g., the lower the time duration) the calibration interval (t₁) 172, the “lower” the number of AND gates 126 the digital high state (1) transitions through. Alternatively, the “larger” (e.g., the greater the time duration) the calibration interval (t₁) 172, the “more” AND gates the digital high state (1) transitions through. In certain implementations, the calibration interval (t₁) may be used to calibrate the voltage droop detector circuit 110. Trimming (e.g., adjust) the calibration interval (t₁) 172 can be for calibration purposes, but, advantageously, as seen in the implementations below, the clarity in resolution has the capability to be modified (e.g., either increasing or decreasing).

In an example operation, the input clock signal (ckin) 151 may be set at 4 gigahertz, and correspondingly, the input clock signal (ckin) period may be 178 is 250 picoseconds. Further, in such an example, one AND gate delay may be set at 10 picoseconds and the calibration interval (t₁) 172 is 100 picoseconds. Accordingly, a digital high state (1) of the output clock signal (ck) 155 can propagate through ten AND gates before the next rising edge of the input clock signal (ckin) 151. Continuing with such an example, as the calibration interval (t₁) 172 is trimmed from 100 picoseconds to 50 picoseconds, the digital high state (1) of the output clock signal (ck) 155 can propagate through five AND gates before the next rising edge of the input clock signal (ckin) 151. Therefore, in response to propagating through five AND gates, at the next rising edge the input clock signal (ckin) 151, the thermometer coded delay line output 122 is 11111 with the remaining code being zeros.

Thus, in response to the base code (e.g., corresponding to AND gates) being 10, for example, the calibration interval (t₁) can be trimmed to 100 picoseconds. And, in response to the base code being 20, for example, then the calibration interval (t₁) can be trimmed to 200 picoseconds.

FIG. 2A is a block diagram of an example pulse generator circuit 200, in accordance with certain implementations. FIG. 2B is a timing diagram representation 259 of the example pulse generator circuit 200 as illustrated in FIG. 2A. As illustrated in FIG. 2A, similar elements to those of FIGS. 1A and 1B are not discussed again for the sake of brevity and conciseness.

As illustrated in FIGS. 2A and 2B, a delay line 204 includes delay elements 118A, 118B, . . . 118 (N-1), and 118N. In certain implementations, the delay elements 118A, 118B, . . . 118 (N-1), and 118N are buffers. In one implementation, as discussed above, the delay period (tₛ), created by the delay elements 118A, 118B, . . . 118 (N-1), and 118N, is lengthened with additional delay elements and shortened with fewer delay elements. However, the pulse generator circuit 200 further includes NOR gate 222 (that outputs a digital low state (0) in response to a digital high state (1) at either NOR gate input). As depicted, the NOR gate 222 can accept at one input a flip-flop output (ckff) 253 and at another input a delayed output (ckffd) 257.

Therefore, in an additional implementation to lengthen or shorten the delay period (tₛ), the pulse generator circuit 200 provides for the appearance that the delay line 204 may be used twice. On further examination, it is the delay period (tₛ) that can be used twice by the NOR gate 222, advantageously allowing the delay line 204 to be half the size of a delay line providing the equivalent delay period (tₛ). Thus, to lengthen or shorten the delay period (tₛ), an output clock signal (ck) pulse width 268 of the output clock signal (ck) 255 may be configured to be adjusted (e.g., trimmed) by modifying the duration of the flip-flop output (ckff) 253, and thus the duration of the delayed output (ckffd) 257 set at respective digital high states (e.g., digital “1”) (i.e., ≥2tₛ).

For example, a duration of the flip-flop output (ckff) 253 and a duration of the delayed output (ckffd) 257 set at respective digital high states (e.g., digital “1”) (i.e., ≥2tₛ) correspond to approximately twice the time taken to get through the delay elements 118A, 118B, . . . 118 (N-1), and 118N. Or, alternatively stated as the duration of flip-flop output (ckff) 253 and the duration of delayed flip-flop output (ckffd) 257 set at respective digital high states correspond to approximately a quantity of the delay elements 118A, 118B, . . . 118 (N-1), and 118N. As illustrated in FIG. 2B, the flip-flop output (ckff) 253 is one input to the NOR gate 222 and the delayed output (ckffd) 257 (delayed by the delay period (tₛ)) is another input to the NOR gate 222, thus in response both the flip-flop output (ckff) 253 and the delayed output (ckffd) 257 being in a digital high state (1), the output clock signal (ck) pulse width 268 of the output clock signal (ck) 255 will be at a digital low state (0) that is approximately two delay periods (2tₛ). In certain aspects, a standard delay line providing a delay period of 2tₛ would have twice the delay elements and thus the delay line 204 would be twice the size to accomplish the equivalent delay period of 2tₛ. Advantageously, by reducing the delay line 204 and the number of the delay elements, valuable integrated circuit space is saved as well as power consumption is reduced by much fewer delay elements.

In an example implementation, with reference to FIG. 2B, in response to a rising edge 250 of an input clock signal (ckin) 251, a “short” (e.g., approximately a gate delay) delay 252 (clk2Q) occurs as the state of the flip-flop 102 is transmitted to the delay line 204. After the delay 252, a rising edge 254 of the flip-flop output (ckff) 253 and a falling edge 256 of the output clock signal (ck) 255 occurs. In response to a digital high state (1) being received by the NOR gate 222, an output of a digital low state (0) is realized as the falling edge 256. After the delay period (tₛ), that is the time to pass the flip-flop output (ckff) 253 through the delay line 204, a rising edge 258 of the delayed output (ckffd) 257 is realized. In response to the rising edge 258, another digital high state (1) can be realized at the other input of the NOR gate 222, thus ensuring the output clock signal (ck) 255 remains in a digital low state (0) for the pulse of the delayed output (ckffd) 257. Further, the rising edge 258 of the delayed output (ckffd) 257 provides a digital high state (1) at the gate 106, that is transmitted to the reset input 116 initiating a reset to a digital low state (0) of the flip-flop 102. As shown, a delay 260 caused by the gate 106 and the flip-flop 102 (clk2Q) occurs before a falling edge 262 of the flip-flop output (ckff) 253. After a second delay period (tₛ) and the delay 260 (repeated the in pulse of the delayed output (ckffd) 257), a falling edge 266 of the delayed output (ckffd) 257 and a rising edge 264 of the output clock signal (ck) 255 is realized. Mathematically, in some cases, the output clock signal (ck) pulse width 268 can be represented as: approximately 2tₛ+OR+clk2Q, or alternatively stated as the combination of twice the time through the delay line 204, the time through the “OR” gate 106, and the flip-flop 102. In some instances, as illustrated in FIG. 2B, the output clock signal (ck) pulse width 268 can be represented as: approximately 2tₛ+OR+R2Q; or alternatively stated as a combination of: a duration of a flip-flop output 253 and a duration of a delayed flip-flop output 257 at respective digital high states, a portion of a time delay of the flip-flop 102 (e.g., from the reset input 116 to Q output 114) and a portion of a time delay of the “OR” gate 106.

As indicted in FIG. 2B, the time between the rising edge 264 of the output clock signal (ck) pulse width 268 and the next rising edge 270 of the input clock signal (ckin) 251 is a calibration interval (t₁) time 272. By comparison, the calibration interval (t₁) 172 in relation to calibration interval (t₁) 272, shows calibration interval (t₁) 272 as “shorter” (e.g., the time of the calibration interval (t₁) 272 is less than the time of the calibration interval (t₁) 172) than the calibration interval (t₁) 172 and thus, the calibration interval (t₁) 272 has been trimmed.

Furthermore, the output clock signal (ck) pulse width 268 is the average of the rising edge 254 and the falling edge 266. In digital systems, with clock signals or square waveforms, the rising and the falling edges represent the transitions between logical states (from low to high or vice versa). Hence, averaging on both rising and falling edges means measurements or calculations are performed considering both transitions. Therefore, such averaging can be based on signal characteristics (such as voltage levels, timing, and/or signal duration) observed at both the rising (low-to-high) and the falling (high-to-low) edges of the waveform.

As illustrated in FIGS. 2A and 2B, the flip-flop output (ckff) 253 and the delayed output (ckffd) 257 are merged into the NOR gate 222. In response to merging of the flip-flop output (ckff) 253 and the delayed output (ckffd) 257 into the NOR gate 222, the output clock signal (ck) pulse width 268 is ≥2tₛ. Further, the only relationship between the output clock signal (ck) 255 and the input clock signal (ckin) 251 is the rising edge 250 of the input clock signal (ckin) 251. Therefore, only the next rising edge 270 of input clock signal (ckin) 251, detected by the flip-flop 102 (e.g., acting as an edge detector) is used to repeat the process described above.

Advantageously, the output clock signal (ck) pulse width 268 can be larger than ½ (input clock signal (ckin) period). Further, the output clock signal (ck) pulse width 268 can be adjusted all the way “up” (over) to a full input clock signal (ckin) period. In a beneficial manner, the pulse generator circuit 200 can trim the calibration interval (t₁) down to “small” values (e.g., at or near zero) as the delay period (tₛ) grows “larger” (i.e., the output clock signal (ck) pulse width 268 grows larger). Further, the pulse generator circuit 200 can trim the calibration interval (t₁) “up” to “large” values (e.g., at or near a full input clock signal (ckin) period) as the delay period (tₛ) “shrinks” (i.e., the output clock signal (ck) pulse width 268 shrinks). Favorably, the pulse generator circuit 200, according to inventive aspects, has no dependence on the input clock state (ckin), and so the calibration interval (t₁) can be trimmed for any interval beyond a half input clock signal (ckin) period to a full input clock signal (ckin) period. Further, beneficially, the size of the delay line 204 can be reduced by 2X in comparison to an equivalent delay line providing an equal delay period (tₛ) of the delay line 204. In addition, without the NOR gate 222, twice as many buffers/delay elements would be used to obtain the same the output as the clock signal (ck) pulse width 268. As an advantage, the pulse generator circuit 10 or 100 are configured to be triggered on the rising edge of the input clock signal (ckin) 251 and independent of the remainder of the input clock signal (ckin) period. To this end, the pulse generator circuit 200 includes the flip-flop 102 as an edge detector or edge filter. For instance, the pulse generator circuit 200, through the flip-flop 102, is sensitive to the clock input signal (ckin) rising edge and since the pulse generator circuit 200 is sensitive to the rising edge, the output clock signal (ck) pulse width 268 can be trimmed beyond half of an input clock period (ckin).

FIG. 3 is a block diagram of an example pulse generator circuit 300, in accordance with certain implementations. As illustrated in FIG. 3, similar elements to those of FIGS. 1A, 1B, and 2A are not discussed again for the sake of brevity and conciseness.

As illustrated in FIG. 3, each of delay elements 318A, 318B, . . . 318 (N-1), and 318N of delay line 304 output to multiplexer 332 as outputs o<0>, o<1>, . . . , o<n-2>, o<n-1>, and on>. It should be understood, the multiplexer 332, often abbreviated as MUX, is designed to select one of several input data lines (that receive the outputs o<0>, o<1>, . . . , o<n-2>, o<n-1>, and o<n>) and route the outputs o<0>, o<1>, . . . , o<n-2>, o<n-1>, and o<n> to a single output line 336 based on control signals (e.g., trim input 334). To place additional control over the trimming aspect, the multiplexer 332 efficiently switches or selects between multiple input signals (e.g., the outputs o<0>, o<1>, . . . , o<n-2>, o<n-1>, and o<n>) and transmits the selected signal to the output line 336. Keeping in mind the number of input lines would determine the number of selection inputs, the trim input 334 determines an input line connected to the output line 336. For example, a<n: 0> multiplexer selects, based upon the trim input 334, one of n-input lines based on log (n) selection inputs, and the delay period (tₛ) is modified (either shortened or lengthened) based on the selected input line.

As depicted in FIG. 3, the example pulse generator circuit 300 can trim the width of the output clock signal (ck) pulse width 268 through the multiplexer 332. In one example, in response to the multiplexer 332 selecting, based on the trim input 334, the 2nd input (e.g., output o<1>), the flip-flop output (ckff) 253 transitions through two delay elements 318A and 318B. Resultingly, the delay period (tₛ) at the output line 336 of the multiplexer 332 is going to be the combined delay from first and second delay elements 318A and 318B (and additional gate delays, such as flip-flop R2Q). Additionally, the output clock signal (ck) pulse width may be greater than or equal to a delay period of 2tₛ corresponding to four delay elements when only 2 delay elements are used. In one example, in response to the multiplexer 332 selecting a 20th input (e.g., output o<19>), the flip-flop output (ckff) 253 transitions through twenty delay elements before being inputted to the multiplexer 332. Accordingly, the delay period (tₛ) at the output line 336 of the multiplexer 332 would be the combined delay from first through twentieth delay elements (and additional gate delays, such as flip-flop R2Q). Furthermore, advantageously, the saving of precious IC board space and power consumption is made clearer when only twenty delay elements are used to produce an output normally requiring forty delay elements.

As stated above, the “larger” (e.g., wider, or longer in time) the output clock signal (ck) pulse width 268, the “smaller” (e.g., narrower, or smaller in time) calibration interval (t₁), the smaller the code at the thermometer coded delay line output 122. In a non-limiting example, assuming calibration interval (t₁) is 100 picoseconds and each delay element 318 delay is 10 picoseconds, then the output code is going to be 10. Continuing with such a non-limiting example, now assume calibration interval (t₁) is 50 picoseconds, then the output code is going to be 5. Therefore, by doing so, the goal is to have a code that is in the desired range (e.g., a clarity of resolution for a voltage droop detector) of a specification. Advantageously, the pulse generator circuit 300 can trim calibration interval (t₁) to have an output code that suits a target code.

In certain implementations, delay elements within box 338 are constructed with CMOS technology having a first voltage threshold (VT)-type, such as an ultra-low voltage threshold (ULVT) or an extra-low voltage threshold (ELVT). It should be understood, an ultra-low voltage threshold refers to the voltage level at that a device, typically a transistor or semiconductor component, operating or switch states. In the context of transistors, particularly in modern semiconductor technologies, a low voltage threshold implies that the transistor turns on or off with very low voltage levels. For instance, in CMOS technology used in integrated circuits, transistors have a specified threshold voltage below that they transition from the “off” state to the “on” state. Advantageously, an ultra-low voltage threshold means the transistors effectively switch or conduct at significantly lower voltage levels than traditional transistors. Several advantages are offered by these ultra-low voltage transistors, including high speed switching, increased energy efficiency, and the ability to operate in low-power or energy-harvesting applications where power availability is limited. Suitably, such transistors find applications in various fields, including, for example, IoT devices, wearable electronics, medical implants, and sensor networks, where operating at ultra-low voltages is useful to extending battery life or functioning with minimal power resources.

In the context of semiconductor technology, particularly related to MOSFETs (Metal-Oxide-Semiconductor Field-Effect Transistors) or CMOS (Complementary Metal-Oxide-Semiconductor) devices, “VT-type” typically refers to the voltage threshold type of a MOSFET. As such, voltage threshold (VT) represents the minimum voltage applied to the gate of a MOSFET to induce a channel between its source and drain regions, allowing current to flow through the transistor. Comparatively, MOSFETs can have different threshold voltage types or categories, such as “low VT” (e.g., ULVT or ELVT) and “high VT,” (e.g., such as above a ULVT or ELVT but below a standard voltage threshold (SVT)) indicating different threshold voltage levels. Advantageously, VT-type categorization helps classify MOSFETs based on their threshold voltage characteristics, which affects their performance and behavior in circuit designs. Correspondingly, MOSFETs with a lower threshold voltage (typically below the standard threshold) are often used in designs requiring faster switching speeds and higher performance but may consume more power at idle states while MOSFETs with a higher threshold voltage (above the standard threshold) are useful for reducing leakage currents, enhancing power efficiency, and maintaining stability in certain circuit configurations.

In certain implementations, delay elements with box 340 are constructed with CMOS technology having a second VT-type, such as a standard voltage threshold (SVT). It should be understood, ULVT, ELVT, and SVT devices refer to different classes or categories of transistors or integrated circuits based on their voltage thresholds. Commonly, SVT devices may be used in typical electronic devices and refer to standard transistors that operate at standard voltage levels and not specifically designed for ultra-low-power or extremely low-voltage applications. While not specialized, SVT devices are suitable for general-purpose electronics, where power consumption and voltage levels are within standard ranges. Distinctively, ULVT and ELVT devices cater to applications requiring high speed switching or operation at extremely low voltage levels, while SVT devices operate at standard voltage levels for general-purpose electronics.

In some implementations, delay elements within the box 338 have a first VT-type, and delay elements within the box 340 have a second VT-type where the first VT-type and the second VT-type are different VT-types. In some implementations, delay elements having a first VT-type are a large majority (e.g., ≥80%) of the delay elements within the delay line 304. In some implementations, delay elements having a first VT-type are a slight majority (e.g., ≥50.1%) of the delay elements within the delay line 304.

FIG. 4A (incorporating FIG. 4B) is a block diagram of an example pulse generator circuit 400, in accordance with certain implementations. As illustrated in FIG. 4A, similar elements to those of FIGS. 1A, 1B, 2A, and 3 are not discussed again for the sake of brevity and conciseness.

As illustrated in FIG. 4A, the one or more delay elements shown as illustrated in FIGS. 1A, 1B, and 2A are replaced with an example telescopic delay line 404. It should be known that a telescopic delay line is a type of delay line used in ICs to create precise delays in signals. Accordingly, telescopic delay lines are commonly employed in applications for precise timing or synchronization, such as in communication systems, signal processing, or clock generation circuits. Descriptively named, the telescopic aspect of a telescopic delay line refers to the construction, that involves multiple stages, segments, or cells, such as delay cell 0 444A, delay cell 1 444B, delay cell 2 444C, and delay cell 3 444D, of delay elements cascaded together. Incrementally, each delay cell typically contributes a “small” (e.g., two or more gate delays) delay to the overall delay line. Moreover, a characteristic of the telescopic delay line 404 is an ability to provide a wide range of selectable delays by adjusting or activating different delay cells or stages within the telescopic delay line 404. Through activation or bypassing specific delay cells 444, the total delay of the signal passing through the telescopic delay line 404 is precisely controlled. Advantageously, telescopic delay lines are flexible and granular in adjusting delays, providing value in applications that demand precise timing control or signal synchronization. Further, telescopic delay lines provide a method to fine-tune or select delays in electronic systems, ensuring proper synchronization of signals in complex digital circuits. One of ordinary skill understands that the delay cells 444 can be implemented using various techniques, such as transmission lines, RC (resistor-capacitor) networks, or switched capacitor circuits, depending on the technology and design requirements without departing from the spirit of the implementations.

As illustrated in FIG. 4B, the example telescopic delay line 404 includes the delay cell 0 444A, the delay cell 1 444B, the delay cell 2 444C, and the delay cell 3 444D. In addition, the telescopic delay line 404 is configured to adjust the output clock signal (ck) pulse width 268 by activating at least one of one or more delay cells. To this end, in certain implementations, a binary-to-one-hot (bin2OH) device 442 may be configured to receive a binary code (TRIM <n: 0>) 434 and transmit a one hot code signal to the telescopic delay line 404. It should be known, a binary-to-one-hot (bin2OH) device is a digital logic component used to convert binary-coded input into a one-hot encoded output. In digital systems, binary encoding represents a numerical value using a sequence of binary bits, where one bit is active (set to 1) at a time. Representatively, in a one-hot code each value in a set with a unique bit pattern, where one bit is active (‘1’) and others are inactive (‘0’). Hence, the bin2OH device, such as the binary-to-one-hot (bin2OH) device 442, takes a binary input, such as the binary code (TRIM <n: 0>) 434, and produces a one-hot encoded output that corresponds to the active bit position in the binary input.

In a non-limiting example, for a 3-bit binary input (e.g., 000, 001, 010, 011, and the like), a bin2OH device produces an 8-bit one-hot encoded output. In response to the binary input being 001, the output is 00000010, indicating the second bit position is active. In operation, the bin20H device 442 performs a transformation from binary representation to a one-hot representation, allowing the telescopic delay line 404 to work with different delay cell schemes for applications.

In certain implementations, at least one delay cell 444 includes elements with the first VT-type, at least one delay cell 444 includes elements with the second VT-type. In certain implementations, at least one delay cell 444 includes the first VT-type and at least one delay cell 444 includes the second VT-type. In certain implementations, the delay cells 444A and 444B include elements of the first VT-type and the delay cells 444C and 444D include elements of the second VT-type. In certain implementations, the delay cells 444A, 444B, and 444C include elements of the first VT-type and delay cell 444D include elements of the second VT-type. In certain implementations, delay cell 444A include elements of the first VT-type and the delay cells 444B, 444C, and 444D include elements of the second VT-type.

Advantageously, power consumption is reduced with the telescopic delay line 404. As illustrated in FIG. 3, the flip-flop output (ckff) 253 passes through the entire delay line 304 all the way to the end. Therefore, each delay element 318A, 318B, . . . 318 (N-1), and 318N in the delay line 304 is switched and that consumes power. In contrast, the telescopic delay line 404 does not use each gate in the telescopic delay line 404 and the inputs to each unused gate in the telescopic delay line 404 are tied down so as not to switch and consume power.

In a non-limiting example, the bin2OH device 442 inputs a selection code to the telescopic delay line 404 for Q0 446A, Q1 446B, Q2 446C, or Q3 446D. In response to the delay cell 0 444A being selected, the Q0 446 is going to be a digital high state (1) and the Q1 446B, Q2 446C, and Q3 446D a digital low state (0). In response to the delay cell 1 444B being selected, the Q1 446B is going to be a digital high state (1) and all the other inputs a digital low state (0) and so on.

Continuing with such an example, initially, the Q0 446A is a digital high state (1) and the Q1 446B is a digital low state (0), the Q2 446C is a digital low state (0), and the Q3 446D is a digital low state (0). In response to the Q0 446A being at a digital high state (1), then the second input of A gate 448 is a digital high state (1) and the second input of C gate 450 is a digital low state (0). As the A gate 448 and the C gate 450 are NAND gates, the A gate 448 is transparent to input 452 (meaning since one input is a digital high state, no matter the input signal on the other input, an inverted input signal is the output). The A gate 448 inverts the input 452, transmits the inverted input to B gate 454, that inverts the input again as output Y (e.g., thus, the input 452 is delayed by two gates; the A gate 448 and the B gate 454). The C gate 450 blocks the input 452 (e.g., meaning since one input is a digital low state, no matter the signal on the other input the output is a digital high state meaning the input 452 is not reproduced). Thus, the output of the C gate 450 is a digital high state (1) and the C gate 450 does not toggle. As the upper input of the B gate 454 is a digital low state, then the output of the B gate 454 is a digital high state. Thus, the input 452 is going from the A gate 448 then the B gate 454 and then output. Hence, the input 452 passes through two gates or alternatively said, the input 452 is delayed by two gates.

In another example operation, in response to the bin2OH device 442 inputting a selection on the Q1 446B, Q1 446B is at a digital high state and the Q0 446A, the Q2 446C, and the Q3 446D is at a digital low state (0). As a digital low state is on the lower input of the A gate 448 (so blocking the input 452) and the A gate output is a digital high state (as any digital low state input on a NAND gate results in a digital high state output) and the B gate 454 becomes transparent to its other input. Continuing, the A gate 448 is not used, so the input 452 passes to the C gate 450 (also transparent) and the C gate 450 inverts the input 452 and transmits the inverted input to A gate 458. At the A gate 458 input 452 is inverted again and transmits the inverted signal to B gate 456 and the B gate 456 inverts input 452 again and transmits the inverted signal to the B gate 454. Wrapping up the flow, the B gate 454 inverts input 452 yet again for a total of four gates (e.g., a delay of four gates) instead of two total gates (e.g., at the Q0 446A being selected).

Deductively, in such examples, it can be concluded that in response to the bin2OH device 442 inputting a selection on the Q2 446C, the input 452 will passes through a total of six gates (e.g., a total of six gate delays). Further, in response to the bin2OH device 442 inputting a selection on the Q3 446D, the input 452 passes through a total of eight gates (e.g., a total of eight gate delays).

From a power aspect, in response to the bin2OH device 442 selecting the Q1 446B, the delay cell 1 444B and the delay cell 0 444A are used, but, advantageously, the delay cell 2 444C and the delay cell 3 444D are not switching at all. Further, the inputs to the delay cell 2 444C and the delay cell 3 444D are “standing still”; hence, the gates are not toggling and power is conserved.

In the non-limiting example of FIG. 4 where four delay cells are in the telescopic delay line 404, one of ordinary skill in the art understands many more delay cells or just two delay cells can be used without departing from the spirit of the implementations.

The subject matter of the claims is not limited to the implementations and illustrations provided herein, the intention is that modified forms of those implementations including portions of implementations and combinations of elements of different implementations be in accordance with the claims. In the development of any such implementation, there is an appreciation as in any engineering or design project, that numerous implementation-specific decisions are made to achieve the developers' specific goals, such as compliance with system-related and business-related constraints, that vary from one implementation to another. Moreover, while such a development effort is complex and time consuming, there is an appreciation for those of ordinary skill having benefit of these embodiments the development would nevertheless be a routine undertaking of design, fabrication, and manufacture.

Reference has been made in detail to various implementations, examples of that are illustrated in the accompanying drawings and figures. In the above embodiments, numerous specific details are set forth to provide a thorough understanding of the embodiments provided herein. However, the embodiments provided herein can be practiced without these specific details. In some other instances, well-known methods, procedures, components, circuits, and networks have not been described in detail so as not to unnecessarily obscure details of the embodiments.

Although the terms first, second, and the like are used herein to describe various elements, these elements should not be limited by these terms. These terms are used to distinguish one element from another. For example, a first element can be termed a second element, and, similarly, a second element is able to be termed a first element. The first element and the second element are both elements, respectively, but they are not to be considered the same element.

The terminology used in the description of the embodiments provided herein is for the purpose of describing implementations and is not intended to limit the embodiments provided herein. As used in the description of the embodiments provided herein and appended claims, the singular forms “a,” “an,” and “the” are intended to include the plural forms as well, unless the context clearly indicates otherwise. The term “and/or” as used herein refers to and encompasses all possible combinations of one or more of the associated listed items. The terms “includes,” “including,” “comprises,” and/or “comprising,” when used in these embodiments, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down;” “upper” and “lower;” “upwardly” and “downwardly;” “below” and “above;” and other similar terms indicating relative positions above or below a given point or element are used in connection with some implementations of various technologies described herein.

While the foregoing is directed to implementations of various techniques described herein, other, and further implementations can be devised in accordance with the embodiments herein, that may be determined by the claims that follow.

Although the subject matter has been described in language specific to structural features and/or methodological acts, the subject matter defined in the appended claims is not necessarily limited to the specific features or acts described above. Rather, the specific features and acts described above are disclosed as example forms of implementing the claims.

What is claimed is:

1. A circuit comprising:
a flip-flop receiving an input clock signal; and
one or more delay elements; wherein the circuit is configured to adjust a pulse width of an output clock signal independent of a clock period of the input clock signal.

2. The circuit of claim 1, wherein the pulse width corresponds to a duration of the output clock signal.

3. The circuit of claim 2, wherein:
the adjustment of the pulse width comprises one of increasing or decreasing the duration of the output clock signal set at the digital low state within the clock period; and
the clock period corresponds to a duration from a first rising edge to a second rising edge of the input clock signal.

4. The circuit of claim 1, wherein:
a duration between the pulse width and the clock period comprises a calibration interval; and
the calibration interval corresponds to an increase in duration of a propagation of the output clock signal.

5. The circuit of claim 1, wherein:
the flip-flop is configured to transmit a flip-flop output to the one or more delay elements, wherein the flip-flop output comprising a state of the flip-flop;
the one or more delay elements are configured to:
delay the flip-flop output by a delay period, and
transmit the delayed flip-flop output to a reset input of the flip flop.

6. The circuit of claim 1, further comprising:
an OR gate;
wherein:
the flip-flop is configured to transmit a flip-flop output to one or more delay elements, wherein the flip-flop output comprises a state of the flip-flop;
the one or more delay elements are configured to:
delay the flip-flop output by a delay period, and
transmit the delayed flip-flop output to a first input of the OR gate, and the OR gate is configured to receive a reset input at a second input of the OR gate.

7. The circuit of claim 1, wherein:
the one or more delay elements is a buffer;
the buffer comprises first and second inverters; and
the output of the first inverter corresponds to the output clock signal.

8. The circuit of claim 1, wherein:
the circuit is configured to adjust the pulse width of the output clock signal by modifying a duration of a flip-flop output at a digital high state, and
the flip-flop output corresponds to an input of the one or more delay elements.

9. The circuit of claim 1, further comprising:
an OR gate; and
a NOR gate, wherein:
an input and an output of the one or more delay elements is coupled as inputs to the NOR gate, wherein:
the input of the one or more delay elements correspond to a flip-flop output;
the output of the one more delay elements correspond to a delayed flip-flop output; and
an output of the NOR gate corresponds to the output clock signal.

10. The circuit of claim 9, wherein a pulse width of output clock signal corresponds to approximately a combination of:
a duration of the flip-flop output and a duration of the delayed flip-flop output at respective digital high states, a portion of a time delay of the flip-flop and a portion of a time delay of the OR gate.

11. The circuit of claim 10, wherein the pulse width of output clock signal is configured to be adjusted by modifying the duration of flip-flop output and the duration of delayed flip-flop output at respective digital high states.

12. The circuit of claim 9, wherein:
the one or more delay elements comprises one or more buffers; and
the duration of the flip-flop output and the duration of the delayed flip-flop output at respective digital high states correspond to approximately a quantity of the one or more buffers.

13. The circuit of claim 9, further comprising:
a multiplexer configured to receive:
respective outputs from each delay element of the one or more delay elements;
a trim signal to adjust the pulse width by selecting a delay element from the one or delay elements to be transmitted by the multiplexer, wherein:
the pulse width is adjusted by increasing or decreasing a quantity of the one or more delay elements; and wherein
the multiplexer is configured to transmit:
a delay output to the OR gate and the NOR gate corresponding to the quantity of delay elements.

14. The circuit of claim 1, wherein at least a first and at least a second of the one or more delay elements include different VT-types.

15. The circuit of claim 1, further comprising:
a telescopic delay line, wherein at least first and second delay cells of two or more delay cells are the one or more delay elements; and
the telescopic delay line is configured to adjust the pulse width by activating at least one of the two or more delay cells.

16. The circuit of claim 15, further comprising:
a binary-to-one-hot (bin2OH) device configured to receive a binary code and transmit a one hot code signal to the telescopic delay line.

17. The circuit of claim 15, wherein:
at least the first delay cell comprises a first VT-type;
at least the second delay cell comprises a second VT-type; and
the first VT-type is different from the second VT-type.

18. The circuit of claim 1, wherein the circuit is configured to adjust the output clock signal for a duration from approximately a half-clock period to the clock period.

19. A circuit comprising:
a flip-flop receiving an input clock signal; and
one or more delay elements, wherein the circuit is configured to adjust a pulse width of an output clock signal, and wherein:
the flip-flop is configured to transmit a flip-flop output signal to the one or more delay elements, wherein the flip-flop output signal comprises a state of the flip-flop;
the one or more delay elements are configured to:
delay the flip-flop output signal by a delay period, and transmit the delayed flip-flop output to a reset input of the flip-flop.

20. The circuit of claim 19, further comprising:
an OR gate configured to receive:
the delayed flip-flop output at a first input of the OR gate, and
the reset input at a second input of the OR gate.

21. A circuit of claim 19, further comprising:
an OR gate, wherein the circuit is configured to adjust the pulse width of the output clock signal independent of a falling edge of the input clock signal.

22. A circuit of claim 19, further comprising:
an OR gate, wherein the circuit is configured to adjust the pulse width of the output clock signal based only on a rising edge of the input clock signal.

23. The circuit of claim 19, wherein the circuit is configured as a clock-edge filter or a clock-edge detector.
